(19) United States
(12) Patent Application Publication
(10) Pub. No.: US 2009/0267145 A1
(43) Pub. Date: Oct. 29, 2009

(54) MOSFET DEVICE HAVING DUAL INTERLEVEL DIELECTRIC THICKNESS AND METHOD OF MAKING SAME

(75) Inventors: Charles Walter Pearce, Emmaus, PA (US); Simon J. Molloy, Allentown, PA (US); Shuming Xu, Schnecksville, PA (US); Xiao Rui Li, Allentown, PA (US)

Correspondence Address: TEXAS INSTRUMENTS INCORPORATED, P O BOX 655474, M/S 3999, DALLAS, TX, 75265, US

(73) Assignee: CICLON SEMICONDUCTOR DEVICE CORP., Bethlehem, PA (US)

(21) Appl. No.: 12/108,045

(22) Filed: Apr. 23, 2008

(51) Int. Cl. H01L 29/78; H01L 21/336

(52) U.S. Cl. 257/336; 438/286; 257/E21.433; 257/E29.266

(57) ABSTRACT

A method of forming a metal-oxide-semiconductor (MOS) device includes the following steps: forming a semiconductor layer of a first conductivity type having source and drain regions of a second conductivity type, a channel region and a lightly-doped drain region formed therein; forming a gate over the channel region proximate an upper surface of the semiconductor layer; after the forming steps, depositing a first dielectric layer having a first thickness over an upper surface of the semiconductor layer; etching the first dielectric layer in a region over the lightly-doped drain proximate to the gate to reduce its thickness; conformably depositing a second dielectric layer having a second thickness over the first dielectric layer, including in the etched region, the second thickness being less than the first thickness; and forming a shielding electrode over the second dielectric layer.

### FIELD OF THE INVENTION

The present invention relates to semiconductor devices and methods of making the same and more particularly to laterally diffused MOS (LDMOS) transistor devices and methods of making the same.

### BACKGROUND OF THE INVENTION

The device performance of MOS devices can be degraded by a phenomenon known as “hot carrier injection” or HCI where the electric field from the drain acts in a manner close to the gate structure to aid the injection of electrons from the active channel of the device into the gate oxide. The electrons remain trapped in the gate oxide resulting in a decrease in device performance including, but not limited to, an increase in the threshold voltage of the device and a reduction in transconductance.

One common method of mitigating the effect of hot carrier injection is to use a dummy gate structure. In this approach, an interlevel dielectric layer is deposited over the active gate and a dummy gate structure is placed on top of the interlevel dielectric layer. An example of such a dummy gate is shown in FIG. 2 of U.S. Pat. No. 7,126,193 to Baiocchi et al., the entirety of which is hereby incorporated by reference herein, and identified by reference number 226. FIG. 2 of Baiocchi et al. is reprinted herein as FIG. 1. The dummy gate partially overlaps the gate structure 222 and extends partially over the drain region. As such, the structure shifts the maximum electric field away from the edge of the active gate 222. The dummy gate is usually electrically connected to the source of the device. This connection provides the added benefit of reducing the gate-to-drain capacitance, a parasitic capacitance that is particularly problematic for high frequency MOSFET.

One disadvantage of the dummy gate approach shown in FIG. 1 to reducing hot carrier injection effect is the inability to optimize the interlevel dielectric thickness to meet all device requirements. Making the interlevel dielectric thickness thin so as to reduce hot carrier injection can determinately affect the breakdown voltage of the device and increase parasitic capacitances. Making this dielectric layer thicker to address these concerns has adverse effects on the resistance of the device to hot carrier injection. Therefore, improved device structures and method of making the same are desired.

### SUMMARY OF THE INVENTION

A method of forming a metal-oxide-semiconductor (MOS) device is provided where the thicknesses of the interlevel dielectric layers of the MOS device can be individually controlled so as to both effectively reduce hot carrier injection into the gate oxide and gate-to-drain parasitic capacitance, so called Miller capacitance.

In embodiments, the method includes the following steps: forming a semiconductor layer of a first conductivity type having source and drain regions of a second conductivity type, a channel region and a lightly-doped drain region formed therein; forming a gate over the channel region proximate an upper surface of the semiconductor layer; after the forming steps, depositing a first dielectric layer having a first thickness over an upper surface of the semiconductor layer; etching the first dielectric layer in a region over the lightly-doped drain proximate to the gate to reduce its thickness; conformably depositing a second dielectric layer having a second thickness over the first dielectric layer, including in the etched region, the second thickness being less than the first thickness; and forming a shielding electrode over the second dielectric layer.

The above and other features of the present invention will be better understood from the following detailed description of the preferred embodiments of the invention that is provided in connection with the accompanying drawings.

### BRIEF DESCRIPTION OF THE DRAWINGS

The accompanying drawings illustrate preferred embodiments of the invention, as well as other information pertinent to the disclosure, in which:

FIG. 1 is a reprint of FIG. 2 of prior art U.S. Pat. No. 7,126,193; and

FIGS. 2-7 illustrate an embodiment of an MOS device according to the prevent invention having various dielectric layers thicknesses optimized for improving device performance and a method of making the same.

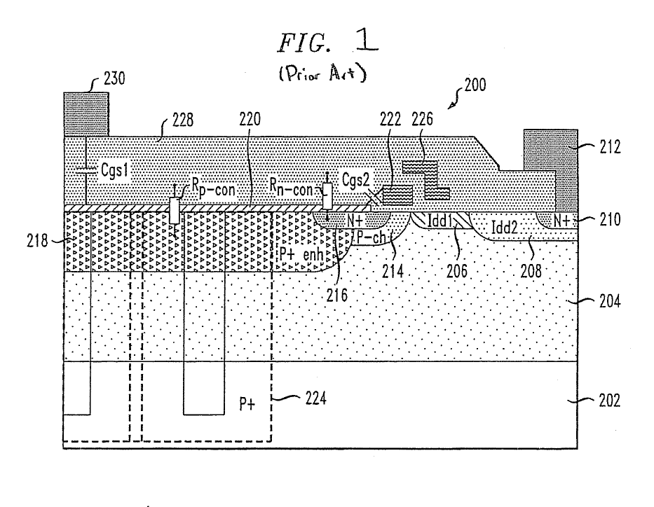

### DETAILED DESCRIPTION

As used herein, the following dopant concentrations are distinguished using the following notations: (a) N++ or P++: dopant concentration of 5×10¹⁹ atoms/cm³ and greater; (b) N+ or P+: dopant concentration of 1×10¹⁸ to 5×10¹⁹ atoms/cm³; (c) N or P: dopant concentration of 5×10¹⁶ to 1×10¹⁸ atoms/cm³; (d) N− or P−: dopant concentration of 1×10¹⁵ to 5×10¹⁶ atoms/cm³; (e) N−− or P−−: dopant concentration <1×10¹⁵ atoms/cm³.

It should be appreciated that, in the case of a simple MOS device, because the MOS device is symmetrical in nature, and thus bidirectional, the assignment of source and drain designations in the MOS device is essentially arbitrary. Therefore, the source and drain regions may be referred to generally as first and second source/drain regions in some cases, respectively, where “source/drain” in this context denotes a source region or a drain region. In an LDMOS device, which is generally not used in a bidirectional mode, such source and drain designations may not be arbitrarily assigned.

A method of forming a metal-oxide-semiconductor (MOS) device is described hereafter where the thicknesses of the interlevel dielectric layers of the MOS device can be individually controlled so as to both effectively reduce hot carrier injection into the gate oxide and gate-to-drain parasitic capacitance, so called Miller capacitance. A MOS device according to the present invention has interlevel dielectric layer (ILD) thicknesses that are selected to optimize various parameters, such as reductions in parasitic capacitance between the source and gate, hot carrier injection and parasitic capacitance between the drain and gate (known as Miller capacitance). Improvements in these parameters help to increase the life of the MOS device as well as its high frequency performance, making the device appropriate for applications where high-frequency operation is desired, such as in a radio frequency (RF) range (e.g., above 1 GHz).

The present invention will be described herein in the context of an illustrative integrated circuit fabrication technology suitable for forming discrete RF LDMOS transistors, as well as other devices and/or circuits. Although implementations of the present invention are described herein with specific reference to an LDMOS device, it is to be appreciated that the techniques of the present invention are similarly applicable to any style MOSFET where either of the primary concerns of HCI improvement and gate-to-drain capacitance reduction are desired. These include, for example, a diffused MOS (DMOS) device or an extended drain MOS device, etc., with or without modifications thereto, as will be understood by those skilled in the art.

It is to be understood that the various layers and/or regions shown in the accompanying figures may not be drawn to scale. Furthermore, certain semiconductor layers and processing steps as will be familiar to those of ordinary skill in this art may have been omitted for ease of explanation and illustration. For example, though not specifically described, various thermal anneals may be performed on the interlevel dielectric layers as desired.

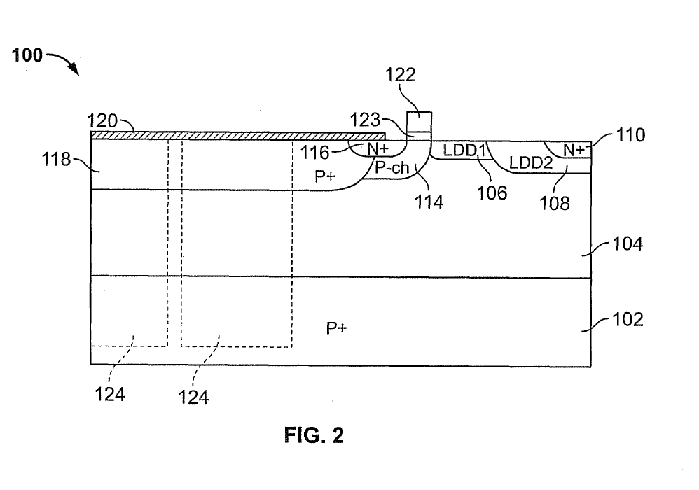

The device structure of the improved MOS device and method of making the same are illustrated in connection with FIGS. 2-7.

FIG. 2 illustrates a cross-sectional view of at least a portion of a semiconductor wafer 100. The wafer 100 includes an LDMOS device formed in a semiconductor layer. The term “semiconductor layer” as may be used herein refers to any semiconductor material upon which and/or in which other materials may be formed. The semiconductor layer may comprise a single layer, such as, for example, the substrate 102, or it may comprise multiple layers, such as, for example, the substrate 102 and an epitaxial layer 104. The semiconductor wafer 100 includes the substrate 102, with or without the epitaxial layer 104, and preferably includes one or more other semiconductor layers formed on the substrate. The term “wafer” is often used interchangeably with the term “silicon body,” since silicon is typically employed as the semiconductor material comprising the wafer. It should be appreciated that although the present invention is illustrated herein using a portion of a semiconductor wafer, the term “wafer” may include a multiple-die wafer, a single-die wafer, or any other arrangement of semiconductor material on or in which a circuit element may be formed.

Although not shown, the region of the LDMOS device shown in the figures represents an active region which is defined by, for example, a peripheral field oxide layer or buried insulator region.

Wafer 100 includes a substrate 102 which is commonly formed of single-crystalline silicon, although alternative materials may be used, such as, but not limited to, germanium (Ge), gallium arsenide (GaAs), etc. Additionally, the substrate 102 may have been modified by adding an impurity or dopant, such as by a diffusion or implant step, to change the conductivity of the material (e.g., n-type or p-type). In a preferred embodiment, the substrate 102 is of highly doped p-type conductivity (p+), and hence may be referred to as a p-substrate.

The LDMOS device of wafer 100 includes an n+ source region 116 and an N+ drain region 110 formed in an epitaxial region 104 of the wafer 100. The LDMOS device further includes a gate 122 formed above a channel region 114 of the device. The gate 122 maybe formed of, for example, polysilicon material, although alternative suitable materials (e.g., metal) may be similarly employed. As is conventional, gate 122 is formed over a thin gate oxide layer 123. The channel region 114 is at least partially formed between the source and drain regions. A drift region is generally formed in the epitaxial layer 104 of the LDMOS device which may comprise a first lightly-doped drain (LDD) region 106 (labeled LDD1) and an optional second LDD region 108 (labeled LDD2) formed over the first LDD region 106 adjacent the drain region 110. The LDMOS device also includes a p+ region 118 formed in the epitaxial layer 104 which connects the p+ substrate to an upper surface of the wafer 100 via one or more trench sinkers 124 (shown in shadow) formed through the epitaxial layer 104. The trench sinkers 124 provide a low resistance (e.g., less than about 1 ohm per square) path between the substrate and the upper surface of the wafer. The trench sinkers may be formed in a conventional manner, such as, for example, by opening windows in the epitaxial layer 104 (e.g., by photolithographic patterning and etching) to expose the substrate 102, and filling the trenches 124 with a conductive material, as will be understood by those skilled in the art. In a preferred embodiment, the trench sinkers 124 are of p-type conductivity.

The p+ region 118 is connected to the n+ source region 116 by a silicide layer 120 for conducting current between the source region 116 and p+ region 118 of the LDMOS device. Suitable materials used to form the silicide layer 120 may include, for example, titanium, cobalt and tungsten, although essentially any material which is capable of forming a low-resistance connection with the silicon may be used.

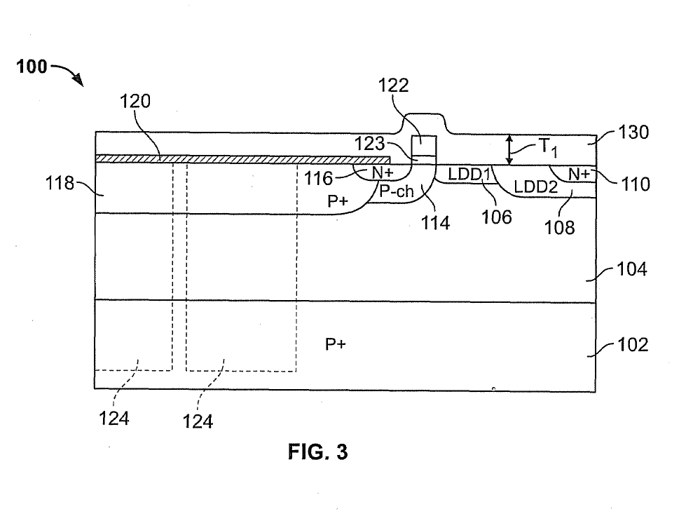

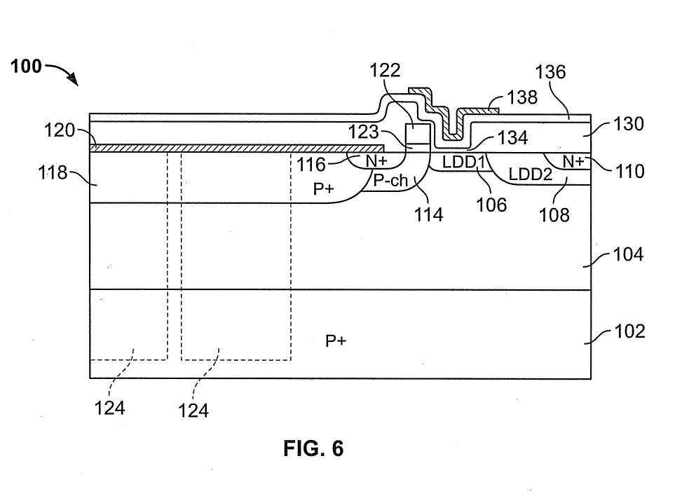

As shown in FIG. 3, a first interlevel dielectric layer 130 is formed over the upper surface of the epitaxial layer 104 and has a thickness T₁. The interlevel dielectric layer 130 is formed from one or more layers of low-k material, such as deposited oxides, which are typically deposited using chemical vapor deposition tools (CVD) that may employ a plasma-enhanced aspect to the deposition (PECVD). Of particular importance, the thickness of the interlevel dielectric layer 130 is selected to provide the desired minimum spacing between the drain region and the gate shield (FIG. 6 (discussed below)) to ensure acceptable gate-to-drain capacitance (Miller capacitance) between the gate 122 and the drain 110. Acceptable levels of Miller capacitance depend at least in part on the intended frequency of use of the device. Devices operating in the MHz range as opposed to those operating in the GHz range can tolerate proportionally much more capacitance. Reductions in gate-to-source parasitic capacitance can also be considered when selecting the thickness of first interlevel dielectric layer 130, though usually not as big a concern as gate-to-drain capacitance. The minimum thickness depends on the voltage that will be developed between the dummy gate (FIG. 6) and drain. This voltage is device specific. Usually, the thickness is selected to be above the thickness required for that voltage value. The limit for the maximum thickness is not as clearly defined. This thickness depends on the overall structure of the device. For example, this thickness adds to the thickness through which contact to the gate, source and/or drain regions will be made. If that thickness is too thick, it can adversely impact the metallization process. In certain embodiments, the interlevel dielectric layer 130 has a thickness between about 1000 to 3000 Angstroms, and more preferably between about 1500 to 2000.

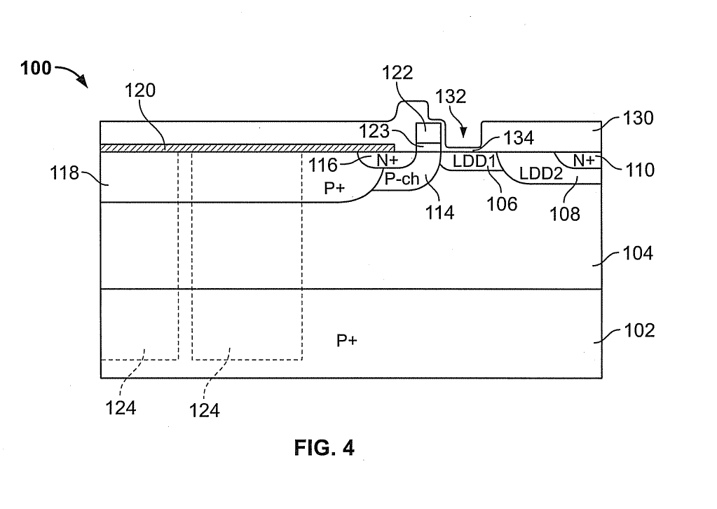

As shown in FIG. 4, an opening 132 in the interlevel dielectric layer 130 is formed, such as using a conventional masking and etching processes used in the art. As shown in FIG. 4, this etch process may leave a thin remnant portion 134 of first interlevel dielectric layer 130 in the opened area 132, so as to avoid etching into epitaxial layer 104 or gate 122, though this is not a requirement. In embodiments, this residual layer 134 can have a thickness from about 0 Å to about 100 Å, and is preferably close to 0 Å. Opening 132 is formed over a portion of the lightly-doped drain region, such as a portion of LDD region 106, and in certain embodiments extends over a portion, but not all, of the upper surface of gate 122. As shown, some oxide may also remain on the side of the gate stack 122. In embodiments, opening 132 will extend over about 50% of the upper surface of the gate 122, allowing for easy alignment of the pattern relative to the gate. In certain embodiments, the opening 132 (and thus the gate shield electrode) will cover the entire upper surface of the gate 122, though possibly at the expense of gate-to-source capacitance. The preferred amount of overlap of the opening 132 locates the termination of the drain field lines at the right edge of the shield electrode, at which point no further increase in overlap is required. In embodiments, the opening 132 extends to about 90 μm or less from the proximate edge of the gate 122.

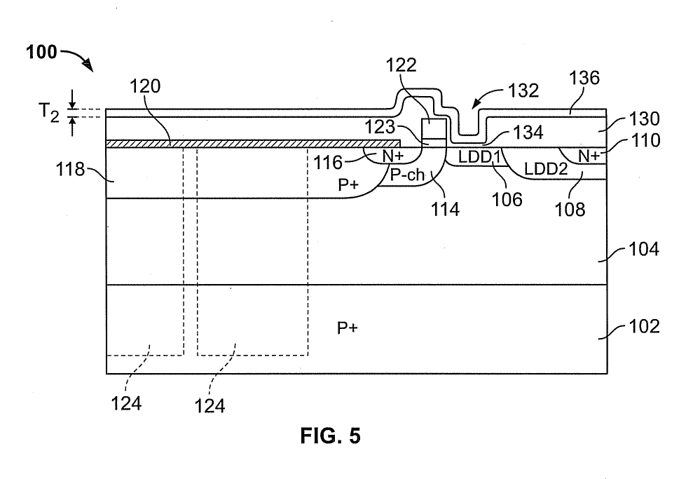

Referring to FIG. 5, after the etch process and any subsequent resist removal and cleaning processes, a second interlevel dielectric layer 136 is deposited over the first interlevel dielectric layer 130 and any residual portion 134 in opening 132. Like interlevel dielectric layer 130, interlevel dielectric layer 136 also preferably includes one or more low-k dielectric material layers, such as a deposited oxide. As can be seen from FIG. 5, the interlevel dielectric layer 136 is conformably deposited over the dielectric layer 130 to mirror the stepped contours of the first interlevel dielectric layer 130 formed by window 132. By use of the term “conformably” it is understood that deposits are generally not perfectly conformal with the underlying layer but rather it is understood that the deposited layer substantially matches the contour of the underlying layer.

Of particular importance, the thickness T₂ of the interlevel dielectric layer 136 is selected to set the distance of the gate shield electrode 138 (FIG. 6) formed thereover from the upper surface of the epitaxial layer 104 in the region of the lightly-doped drain in order to optimize the reduction in hot carrier injection. More specifically, the thickness is selected so as to move the electric field lines extending from the drain away from the corner of the gate to a location that will be effective in hot carrier injection. The lower limit of the acceptable thickness range for the thickness of layer 136 is determined by the voltage that would be developed across the oxide. The potential in the LDD region will be close to the drain potential and the source is typically at ground. Therefore, a voltage will exist between the gate shield electrode 138 and the LDD region. The dielectric layer 136 should be able to sustain that voltage along with some amount of safety margin. In certain embodiments, the interlevel dielectric layer 136 has a thickness less than about 2000 Å, and in certain embodiments, less than about 1200 Å and more preferably between about 500-1000 Å.

As described above, the method of fabricating an MOS transistor allows for the individual optimization of the thicknesses of the interlevel dielectric layers 130 and 136 to improve device performance and reliability. It should be understood that the thickness of the remnant portion 134 of the first interlevel dielectric layer can be considered when selecting the desired thickness of the second interlevel dielectric layer 130 deposited thereover, to the extent the thickness of the remnant portion 134 is not negligible. Likewise, the thickness that the second interlevel dielectric layer 136 contributes to the overall thickness of the stack of the first and second interlevel dielectric layers 130, 136 in the area of the drain contact can also be considered in selecting the original thickness of the first interlevel dielectric layer 130.

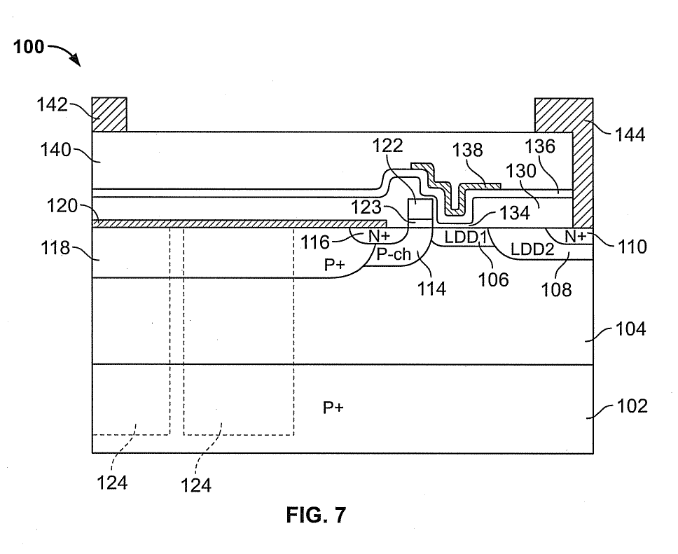

As shown in FIG. 6, a conductive shielding electrode 138, also referred to herein as a dummy gate, is formed over the dielectric layer 136 at least partially between the gate 122 and the drain region 110. The dummy gate 138 is spaced laterally from the gate 122. Although not shown, in an exemplary LDMOS device, the dummy gate 138 is electrically connected (i.e., strapped) to the source region 116. Coupling the dummy gate to the source region allows electric field lines from the drain that would otherwise terminate on the gate to terminate on the source, which reduces the gate-to-drain capacitance. Exemplary materials for the dummy gate include, for example, doped polysilicon, various silicides or metals, and combinations thereof. In one embodiment, a layer of conductive material is conformably deposited over second interlevel dielectric layer 136, followed by masking and etching steps to form the dummy gate structure 138 shown in FIG. 6. In some embodiments, as shown in FIG. 6, the dummy gate 138 extends along the opened region 132 formed in the dielectric layer 130 and beyond to extend over the thicker portion of interlevel dielectric layer 130 that laterally borders this region over the LDD1 regions 106 and/or LDD2 region 108. The dummy gate 138 should not extend so far as to interfere with the formation of drain contact 144 (FIG. 7) or to cause a short therewith. The dummy gate's affect on the breakdown voltage of the device should also be considered. In embodiments, the dummy gate 138 extends less than about 1.3 μm from the proximate edge of the gate 122.

In some embodiments, also shown in FIG. 6, the dummy gate 138 extends along the lateral surface of the gate 122 and overlaps, at least partially as shown, a portion of the upper surface of the gate 122. As discussed above, the preferred amount of overlap of the opening 132 is that amount necessary to locate the termination of the drain field lines at the right edge of the dummy gate 138, at which point no further increase in overlap is required. However, embodiments are also contemplated where the dummy gate-to-active gate overlap is zero or the dummy gate is even offset from the active gate 122.

As shown in FIG. 7, after formation of the dummy gate 138, various processes are performed to complete the device. A third insulating layer 140 is deposited over the structure of FIG. 6 in order to electrically isolate the source, drain and gate contacts of the device as well as to protect the device and planarize the structure. The insulating layer 140 may comprise an oxide, for example, silicon dioxide (SiO₂), although alternative materials, such as low-k dielectric materials or combinations of materials, may be used for forming the insulating layer 140. It is to be appreciated that the insulating layer 140 or other insulating layers described herein may comprise a multiple-layer structure. Furthermore, the insulating layer 140 may include one or more electrically isolated conductive layers. An opening is formed through dielectric layer 140 to electrically connect a drain contact 144 to the drain 110. A gate contact 142 is also formed and electrically connected to the gate 122. Electrical contact to the source region 116 may be made from a bottom of the substrate 102 by way of the trench sinkers 124.

The dummy gate 138 beneficially reduces a Miller capacitance (Cgd) between the gate and drain region of the LDMOS device, thereby improving the high-frequency performance of the device. The thickness of the dielectric layer 130 formed over the drain region, which controls the capacitance formed between the metal layers and various parts of the underlying device, can be optimized to minimize this capacitance without unduly affecting hot carrier injection because the fabrication method, and resulting structure, allow for the separate optimization of the distance between the shield plate and the upper surface of the epitaxial layer through control of the thickness of the second interlevel dielectric layer 136. Careful control of this dielectric layer thickness allows for optimal location of the electric field away from the gate corner so as to reduce hot-carrier induced degradation in the device. It should be appreciated that the deposition thickness of the interlevel dielectric layers is a parameter that can be readily controlled, allowing for precise device configurations.

Further, thinning the dielectric layer only in the region proximate the gate allows for the reduction of hot carrier injection without adversely affecting the breakdown voltage of the device. While this is not necessarily a concern with most RF devices, it is a significant concern with power LDMOS devices.

Various simulations were run on the device described above in connection with FIGS. 2-7, and it was found generally that there are tradeoffs that should be balanced in the device design. In the simulations, the thickness of the interlevel dielectric layer 136 were varied for a fixed thickness value for interlevel dielectric layer 130. The breakdown voltage of the device advantageously increases with the thickness of dielectric layer 136, and reaches a peak at about 1200 Å in thickness, but the gate-to-drain capacitance (Cgd) increases with the thickness of the dielectric layer 136. The gate-to-drain capacitance (Cgd) will decrease as width of the opening 132 for the shield dielectric layer 136 increases, but the breakdown voltage will also decrease. The maximum opening width is also constrained by the total extension of the shield electrode 138 from the gate edge. It is desirable to form opening 132 but it does not have to be very wide to be effective. Balancing all factors, it is preferred to have the opening 132 extend no more than about 0.9 μm from the proximate edge of the gate 122. Further, increasing the shield extension (i.e., the portion of the shielding electrode 138 that overlies first dielectric layer 130) to more than 1.3 μm from the edge of the gate 122 starts to have a significant lowering affect on the breakdown voltage of the device. In embodiments, an optimal balance of effective shielding, gate-to-drain capacitance and breakdown voltage is provided by a device having a dielectric thickness of 900 Å for layer 136 with a window opening 132 of about 0.8 μm and an extension of shield electrode 138 over dielectric layer 130 to about 1 μm from the edge of the gate 122.

Although the invention has been described in terms of exemplary embodiments, it is not limited thereto. Rather, the appended claims should be construed broadly to include other variants and embodiments of the invention that may be made by those skilled in the art without departing from the scope and range of equivalents of the invention.

What is claimed is:

1. A method of forming a metal-oxide-semiconductor (MOS) device, comprising:
forming a semiconductor layer of a first conductivity type having source and drain regions of a second conductivity type, a channel region and a lightly-doped drain region formed therein;
forming a gate over the channel region proximate an upper surface of the semiconductor layer;
after the forming steps, depositing a first dielectric layer having a first thickness over an upper surface of the semiconductor layer;
etching the first dielectric layer in a region over the lightly-doped drain proximate to the gate to reduce its thickness;
conformably depositing a second dielectric layer having a second thickness over the first dielectric layer, including in the etched region, the second thickness being less than the first thickness; and
forming a shielding electrode over the second dielectric layer.

2. The method of claim 1, wherein the first and second thicknesses are set to effectively reduce Miller capacitance and hot carrier injection into a gate oxide.

3. The method of claim 1, wherein the shielding electrode extends along an upper surface of the second dielectric layer in the etched region of the first dielectric layer.

4. The method of claim 3, wherein the shielding electrode extends over a portion of an upper surface of the gate.

5. The method of claim 4, wherein the step of etching the first dielectric layer etches a portion of the first dielectric layer formed over the gate.

6. The method of claim 5, wherein the shielding electrode has a stepped shape over the upper surface of the gate.

7. The method of claim 1, wherein the first thickness is between about 1000 to 3000 Å.

8. The method of claim 1, wherein the second dielectric thickness is less than about 1200 Å.

9. The method of claim 1, wherein the shielding electrode extends along an upper surface of the second dielectric layer in the etched region of the first dielectric layer and over a thicker portion of the first dielectric layer adjacent the etched region towards the drain region.

10. The method of claim 9, wherein the shielding electrode extends over a portion of an upper surface of the gate.

11. The method of claim 9, wherein said etched region extends a distance less than or equal to about 0.9 μm and the shielding electrode extends a distance less than or equal to about 1.3 μm from a proximate edge of the gate.

12. The method of claim 1, wherein said shielding electrode is electrically coupled to said source region.

13. A metal-oxide-semiconductor (MOS) device, comprising:
a semiconductor layer of a first conductivity type, the semiconductor layer having source and drain regions of a second conductivity type, a channel region and a lightly dope drain region formed therein;
a gate formed proximate an upper surface of the semiconductor layer over the channel region;
a dielectric layer formed along the upper surface of the semiconductor layer, wherein the dielectric layer has a region of reduced thickness covering a portion of the gate and extending to cover a portion of the lightly-doped drain region proximate the gate; and
a shielding electrode formed conformably over the dielectric layer and extending from over an upper surface of the gate to a point laterally beyond the region of reduced thickness.

14. The MOS device of claim 13, wherein the gate is formed over a gate oxide and wherein the shielding electrode is spaced from the upper surface of the semiconductor layer in the region of reduced thickness a distance effective for reducing hot carrier injection into the gate oxide.

15. The MOS device of claim 14, wherein the region of reduced thickness has a thickness less than about 1200 Å.

16. The MOS device of claim 13, wherein a thicker portion of the dielectric layer formed over the lightly-doped drain adjacent the region of reduced thickness has a thickness effective for reducing Miller capacitance.

17. The MOS device of claim 16, wherein the thickness of the thicker portion is between about 1000 to 3000 Å.

18. The MOS device of clam 13, wherein said shielding electrode is electrically coupled to said source region.

19. The MOS device of claim 13,
wherein the shielding electrode extends along an upper surface of the thicker portion of the dielectric layer formed over the lightly-doped region adjacent the region of reduced thickness a distance less than or equal to about 1.3 μm from a proximate edge of the gate, and
wherein the portion of the region of reduced thickness extending over the lightly-doped drain region a distance less than or equal to about 0.9 μm from the proximate edge of the gate.

20. A method of forming a laterally diffused metal-oxide-semiconductor (LDMOS) device, comprising:
forming a semiconductor layer of a first conductivity type having source and drain regions of a second conductivity type, a channel region and a lightly-doped drain region formed therein;
forming a gate and a gate dielectric layer over the channel region proximate an upper surface of the semiconductor layer;
after the forming steps, depositing a first interlevel dielectric layer over an upper surface of the semiconductor layer, the first interlevel dielectric layer formed to a thickness effective for reducing gate-to-drain parasitic capacitance in the LDMOS device;
etching the first dielectric layer to form an opening in the first dielectric layer overlapping at least a part of an upper surface of the gate and a part of the lightly-doped drain proximate to the gate;
conformably depositing a second dielectric layer having a second thickness over the first dielectric layer, the second thickness being less than the first thickness; and
conformably depositing a conductive layer over the second dielectric layer and etching the conductive layer to form a shielding electrode, the shielding electrode extending at least partially over the gate to a point over the lightly-doped drain region past the opening, wherein the second thickness is selected to space the shielding electrode from the upper surface of the semiconductor layer a distance effective for reducing hot carrier injection in the gate dielectric layer.

21. The method of claim 20, wherein the first thickness is between about 1500 to 2000 Å and the second thickness is less than about 12000 Å.

22. The method of claim 20, wherein said shielding electrode is electrically coupled to said source region.
